(19) United States
(12) Patent Application Publication
(10) Pub. No.: US 2008/0121370 A1
(43) Pub. Date: May 29, 2008

(54) HEAT DISSIPATION DEVICE WITH A HEAT PIPE

(75) Inventors: Wen-Li Luo, Shenzhen (CN); Shi-Wen Zhou, Shenzhen (CN); Chun-Chi Chen, Taipei Hsien (TW)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Taipei Hsien (TW)

(21) Appl. No.: 11/564,274

(22) Filed: Nov. 28, 2006

(51) Int. Cl. H05K 7/20

(52) U.S. Cl. 165/80.3; 361/700; 165/104.33

(57) ABSTRACT

A heat dissipation device includes a heat spreader (20), a heat sink (10) attached to the heat spreader (20), a sleeve (40) and a heat pipe (30). The heat spreader (20) is for contacting a heat-generating electronic device. The heat sink (10) includes a base (12) and a plurality of fins (14, 15) extending from the base (12). The sleeve (40) is inserted into a through hole (16) defined in the fins (14, 15). The heat pipe (30) includes an evaporating portion (31) sandwiched between the heat spreader (20) and the base (12), and a condensing portion (33) received in the sleeve (40).

### BACKGROUND OF THE INVENTION

1. Field of the Invention

The present invention generally relates to heat dissipation devices, and more particularly to a heat dissipation device having a heat pipe for cooling an electronic component, such as an integrated circuit package.

2. Description of Related Art

Electronic components, such as central processing units (CPUs) comprise numerous circuits operating at high speed and generate substantial heat. Under most circumstances, it is necessary to cool the CPUs in order to maintain safe operating conditions and assure that the CPUs function properly and reliably. In the past, various approaches have been used to cool electronic components. Typically, a finned metal heat sink is attached to an outer surface of the CPU to remove the heat therefrom. The heat absorbed by the heat sink is then dissipated to ambient air. The related finned metal heat sink is made of highly heat-conductive metal, such as copper or aluminum, and generally comprises a base for contacting the CPU to absorb the heat therefrom and a plurality of fins formed on the base for dissipating the heat. However, as the operating speed of electronic components has increased markedly in recent years, such a heat sink, which transfers the heat only by metal conduction cannot fulfill the requirements of a modern CPU. The heat of the bottom of the metal heat sink cannot transfer to the whole heat dissipation device quickly enough.

Heat pipes, which operate by phase change of working liquid sealed in a hollow pipe, have been widely used due to their excellent heat transfer properties. Accordingly, heat dissipation devices equipped with heat pipes are devised in various manners and widely used.

A conventional heat dissipation device with a heat pipe includes a plurality of fins. The fins define a through hole containing a heat pipe. The heat pipe is directly soldered to the fins. However, contact area between the heat pipe and the fins is small. The heat pipe cannot adequately contact the fins. Therefore, the heat accumulated in the heat pipe cannot be quickly transferred to the fins. Heat dissipation capability of the heat dissipation device can therefore be seen to require further improvement.

What is needed, therefore, is a heat dissipation device, which can overcome the above-described disadvantages.

### SUMMARY OF THE INVENTION

According to an embodiment of the present invention, a heat dissipation device includes a heat spreader, a heat sink attached to the heat spreader, a sleeve and a heat pipe. The heat spreader contacts a heat-generating device. The heat sink includes a base and a plurality of fins extending from the base. The sleeve is inserted into a through hole defined in the fins. The heat pipe includes an evaporating portion sandwiched between the heat spreader and the base, and a condensing portion received in the sleeve.

Other advantages and novel features will become more apparent from the following detailed description of preferred embodiments when taken in conjunction with the accompanying drawings, in which:

### BRIEF DESCRIPTION OF THE DRAWINGS

Many aspects of the present heat dissipation device can be better understood with reference to the following drawings. The components in the drawings are not necessarily drawn to scale, the emphasis instead being placed upon clearly illustrating the principles of the present heat dissipation device. Moreover, in the drawings, like reference numerals designate corresponding parts throughout the several views.

FIG. 1 is an exploded, isometric view of a heat dissipation device in accordance with a preferred embodiment of the present invention;

FIG. 2 is another view of FIG. 1; and

FIG. 3 is an assembled view of FIG. 1.

### DETAILED DESCRIPTION OF THE INVENTION

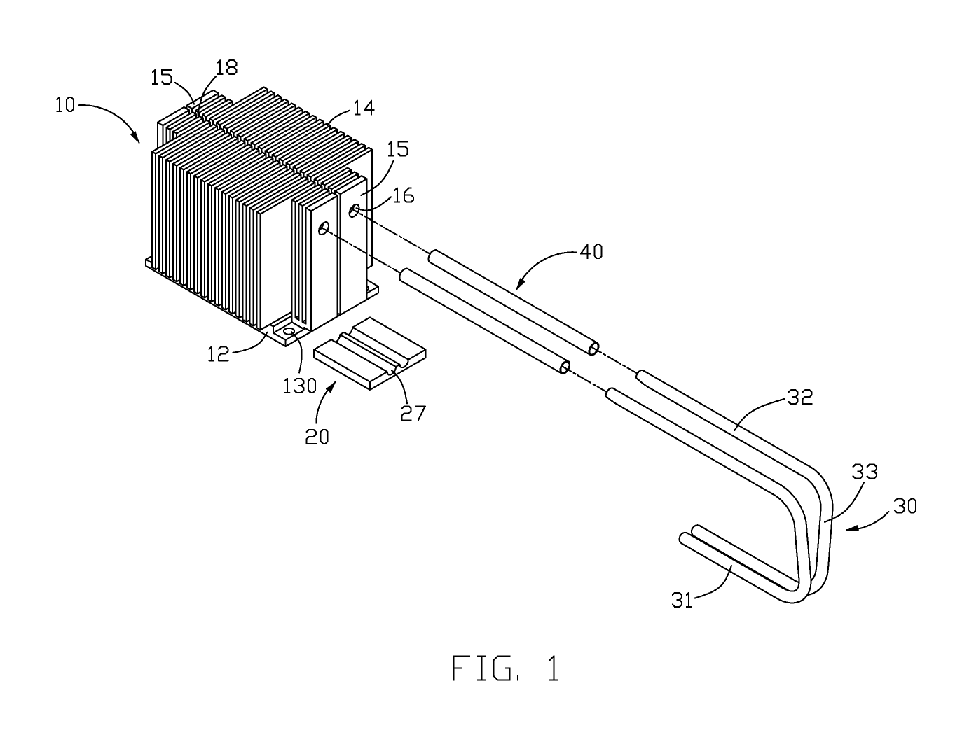

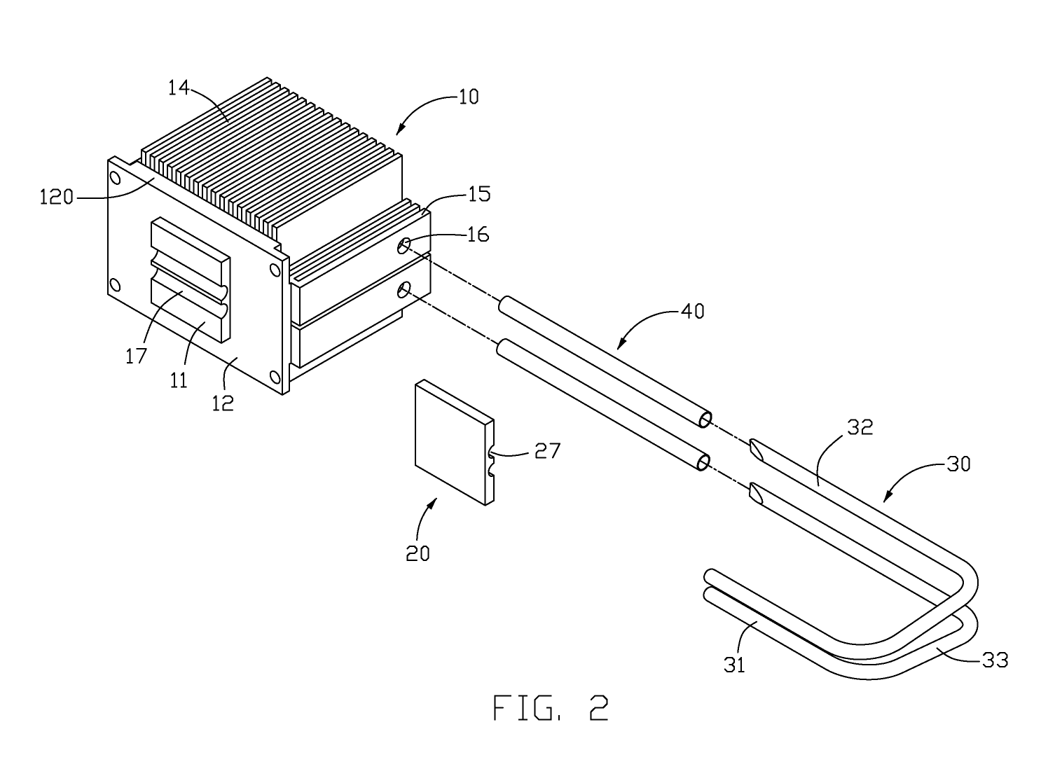

Referring to FIG. 1 and FIG. 2, a heat dissipation device of the preferred embodiment of the present invention is mounted onto a printed circuit board (not shown) to remove heat from a heat-generating electronic device mounted on the printed circuit board, such as a CPU (not shown). The heat dissipation device comprises a heat sink 10, a first heat spreader 20 attached to a bottom of the heat sink 10 and two heat pipes 30 connecting with the first heat spreader 20 and heat sink 10. The heat dissipation device further comprises two sleeves 40.

The first heat spreader 20 is a metal plate having high heat conductivity, and has a rectangular configuration. The first heat spreader 20 comprises a flat bottom surface (not labeled) for contacting the CPU and a top surface opposite to the bottom surface thereof. Two parallel and adjoining grooves 27 are defined in a top portion of the first heat spreader 20 for receiving the heat pipes 30. The grooves 27 are located at a center of the first heat spreader 20.

The heat sink 10 is an aluminum extrusion type heat sink. The heat sink 10 comprises a base 12 and a plurality of first fins 14 mounted on the base 12. A projection 120 is formed on a top surface of the base 12. The first fins 14 extend upwardly from the top surface of the projection 120. The first fins 14 transversely extend beyond two opposite ends of the projection 120. A plurality of parallel second fins 15 extend upwardly from the top surface of the projection 120. The second fins 15 are located at two sides of the first fins 14 and extend longitudinally beyond the other two opposite ends of the projection 120. The heat sink 10 defines a pair of separate through holes 16 extending longitudinally through the first fins 14 and second fins 15. The through holes 16 are located adjacent to top portions of the first and second fins 14, 15. An elongated split 18 extends longitudinally through a center portion of the first fins 14 and second fins 15 along a top-to-bottom direction. The two through holes 16 are located at flanks of the split 18. The base 12 defines four mounting holes 130 at four corners thereof. Four fasteners (not shown) extend through the four mounting holes 130 to mount the heat sink 10 onto the printed circuit board. A second heat spreader 11 extends downwards from the bottom surface of the base 12. The second heat spreader 11 has a configuration similar to the first heat spreader 20. Two parallel grooves 17 are defined in a bottom portion of the second heat spreader 11 positioned corresponding to the grooves 27 of the first heat spreader 20 for receiving the heat pipes 30.

The heat pipes 30 are U-shaped. Each of the heat pipes 30 comprises a horizontal evaporating portion 31, a condensing portion 32 parallel to the evaporating portion 31, and an adiabatic portion 33 connecting with the evaporating portion 31 and the condensing portion 32.

The sleeves 40 are made of heat conductive material, such as copper. Each of the sleeves 40 has a tube configuration. The sleeve 40 has a thin wall. The external diameter of the sleeve 40 is slightly smaller than that of the through hole 16. The length of the sleeves 40 is larger than that of the through holes 16 and smaller than that of the condensing portions 32 of the heat pipes 30.

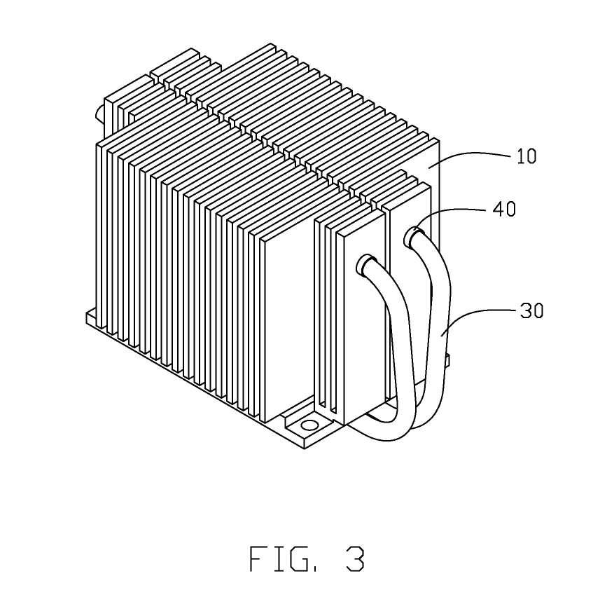

As shown in FIG. 3, in assembly, the sleeves 40 are inserted in the through holes 16 of the first fins 14 and the second fins 15. The sleeves 40 are expanded outwardly by a specific tool (not shown) such that outer circumferential surfaces of the sleeves 40 have an interference fit with the first and second fins 14, 15 and adequately contact with inner surfaces of the through holes 16. The condensing portions 32 of the heat pipes 30 are then soldered into the sleeves 40. Simultaneously, the evaporating portions 31 of the heat pipes 30 are soldered into the channels (not labeled) defined by the grooves 27 of the first heat spreader 20 and the grooves 17 of the second heat spreader 11.

In use, The first heat spreader 20 absorbs the heat generated by the CPU. Then a part of the heat accumulated in the first heat spreader 20 is absorbed by the evaporating portions 31 of the heat pipes 30 and is transferred to condensing portion 32 via the adiabatic portions 33. The heat is transferred to the first fins 14 and the second fins 15 via the sleeves 40. Another part of the heat accumulated in the first heat spreader 20 is transferred to the second heat spreader 11 of the heat sink 10. The heat absorbed by the second heat spreader 11 is transferred to the first fins 14 and the second fins 15 via the base 12. Thus the heat generated by the CPU can be quickly and evenly transferred to the first fins 14 and the second fins 15 and then finally dissipated to ambient environment.

Because the sleeves 40 are expanded outwardly, the outer walls of the sleeves 40 closely contact the inside walls of the through holes 16 in the first fins 14 and the second fins 15. The condensing portions 32 of the heat pipes 30 are inserted in the sleeves 40, so the inside walls of the sleeves 40 can closely contact the condensing portions 32 of the heat pipes 30, and there is a large contact area between the heat pipes and the sleeves 40. The heat accumulated in the condensing portions 32 of the heat pipes 30 is transferred to the first fins 14 and the second fins 15 of the heat sink 10 more evenly than that the heat pipes 30 directly contact the heat sink 10.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device comprising:
a heat spreader for contacting a heat-generating device;
a heat sink attached to the heat spreader, the heat sink comprising a base and a plurality of fins extending from the base, a through hole extending across the fins;
a sleeve inserted in the through hole defined in the fins; and
a heat pipe comprising an evaporating portion sandwiched between the heat spreader and the base, and a condensing portion received in the sleeve.

2. The heat dissipation device as described in claim 1, wherein the outer wall of the sleeve has an interference fit with the fins at the through hole of the fins.

3. The heat dissipation device as described in claim 1, wherein the base comprises an upper projection, and the fins extend upwardly from a top surface of the projection.

4. The heat dissipation device as described in claim 3, wherein an additional heat spreader extends downwards from a bottom surface of the base.

5. The heat dissipation device as described in claim 4, wherein a groove is defined in a bottom portion of the additional heat spreader.

6. The heat dissipation device as described in claim 5, wherein a groove is defined in a top portion of the heat spreader, corresponding to the groove of the additional heat spreader for receiving the heat pipe.

7. The heat dissipation device as described in claim 1, wherein a split extends longitudinally across the fins.

8. The heat dissipation device as described in claim 1, wherein the fins and the base as formed as a monolithic piece.

9. The heat dissipation device as described in claim 8, wherein the heat sink is made of aluminum extrusion.

10. A heat sink assembly, comprising:
a heat sink made of aluminum extrusion, having a through hole extending through the heat sink;
a sleeve received in the through hole and expanded outwardly to have an interference fit with the heat sink; and
a heat pipe having a portion for thermally connecting with a heat-generating electronic device and another portion soldered into the sleeve.

11. The heat dissipation assembly as described in claim 10, wherein the heat sink comprises a base and a plurality of fins extending from the base.

12. The heat dissipation assembly as described in claim 11, wherein the heat pipe comprises an evaporating portion received in the base of the heat sink, and a condensing portion received in the sleeve.

13. The heat dissipation assembly as described in claim 12, wherein the base comprises a first heat spreader and a second heat spreader, and the evaporating portion is sandwiched between the first and second heat spreaders.

14. The heat dissipation assembly as described in claim 13, wherein an elongated split extends longitudinally through a center portion of the fins along a top-to-bottom direction.

15. The heat dissipation assembly as described in claim 14, wherein the fins comprise first fins and second fins located at two sides of the first fins.

16. A method of assembling a heat pipe to a heat sink, comprising steps of:
defining a hole in the heat sink;
inserting a metallic sleeve into the hole;
inflating the metallic sleeve to intimately contact the heat sink; and
soldering the heat pipe into the metallic sleeve.

17. The method as described in claim 16, wherein the metallic sleeve is made of copper.

18. The method as described in claim 16, wherein the heat sink has a base and a plurality of fins extending upwardly from the base, and the hole is defined in the fins.

19. The method as described in claim 18, wherein the heat sink is made of aluminum extrusion.

20. The method as described in claim 19, wherein the heat pipe has a condensing section soldered in the sleeve and an evaporating section adapted for thermally connecting with a heat-generating electronic device.
